(19) United States
(12) Patent Application Publication
(10) Pub. No.: US 2011/0249938 A1
(43) Pub. Date: Oct. 13, 2011

(54) OPTICAL GRATING COUPLER

(75) Inventors: Long Chen, Matawan, NJ (US); Liming Zhang, Marlboro, NJ (US); Christopher Doerr, Middletown, NJ (US); Nicolas Dupuis, New York, NY (US)

(73) Assignee: Alcatel-Lucent USA, Incorporated, Murray Hill, NJ (US)

(21) Appl. No.: 12/756,166

(22) Filed: Apr. 7, 2010

(51) Int. Cl. G02B 6/34; G02B 6/26; H01L 21/465; G02B 6/10

(52) U.S. Cl. 385/37; 385/130; 385/50; 438/31; 257/E21.485

(57) ABSTRACT

An apparatus includes a crystalline inorganic semiconductor substrate. A planar optical waveguide core is located over the substrate such that a first length of the planar optical waveguide core is directly on the substrate. A regular array of optical scattering structures is located within a second length of the planar optical waveguide core. A cavity is located in the substrate between the regular array and the substrate.

### TECHNICAL FIELD

This application is directed, in general, to optical devices and, more specifically, to an optical coupler.

### BACKGROUND

Some optical devices utilize a planar waveguide formed on a substrate, such as silicon-on-insulator (SOI) or InGaAsP on InP. Often it is necessary to couple the planar waveguide to a fiber waveguide to transmit an optical signal to or from the planar waveguide.

### SUMMARY

One aspect provides an apparatus that includes a crystalline inorganic semiconductor substrate. A planar optical waveguide core is located over the substrate such that a first length of the planar optical waveguide core is directly on the substrate. A regular array of optical scattering structures is located within a second length of the planar optical waveguide core. A cavity is located in the substrate between the regular array and the substrate.

Another aspect provides a method. The method includes providing a semiconductor substrate having a planar optical waveguide core located thereover. A regular array of optical scattering structures is located within the planar optical waveguide core. A portion of the substrate is removed to form a cavity located between the regular array and a remaining portion of the substrate.

Yet another aspect provides a method. The method includes providing a crystalline semiconductor substrate having a planar waveguide located thereover, a regular array of optical scattering structures located within the planar optical waveguide core, and a gap located between the substrate and the regular array. An optical fiber waveguide is positioned to illuminate the regular array such that light from the optical fiber waveguide is coupled to the planar waveguide.

### BRIEF DESCRIPTION

Reference is now made to the following descriptions taken in conjunction with the accompanying drawings, in which:

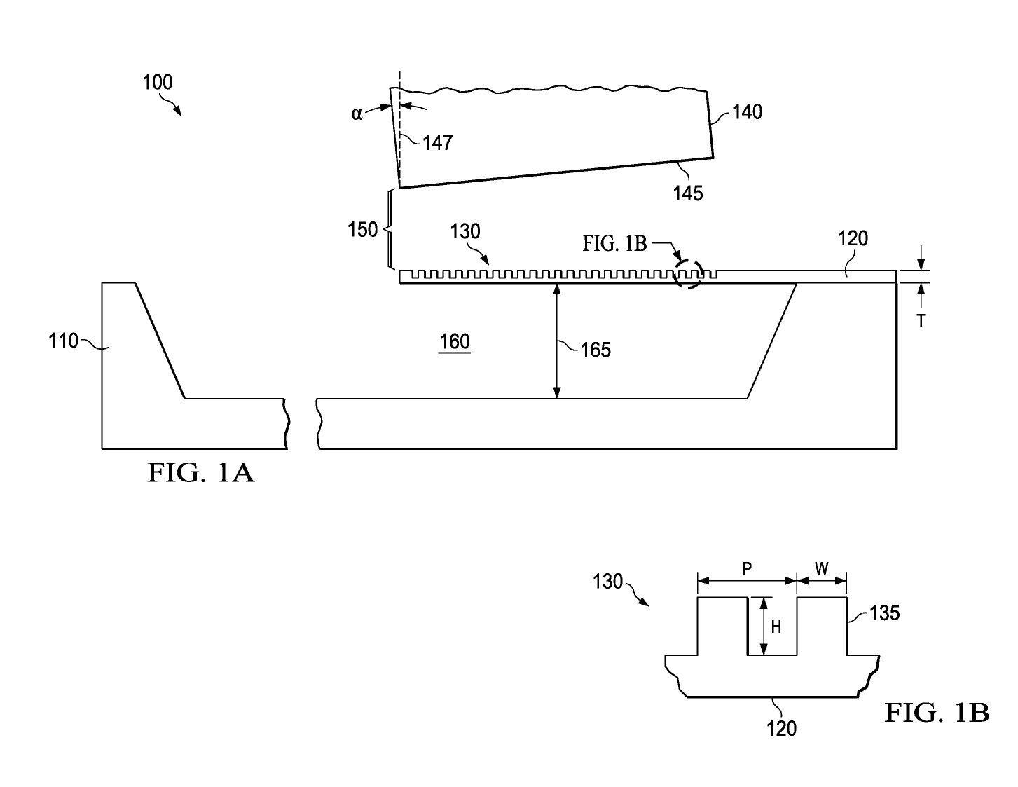

FIGS. 1A and 1B illustrate an embodiment of an apparatus that includes a regular array of optical scattering elements configured to interface a fiber optical waveguide to a planar optical waveguide;

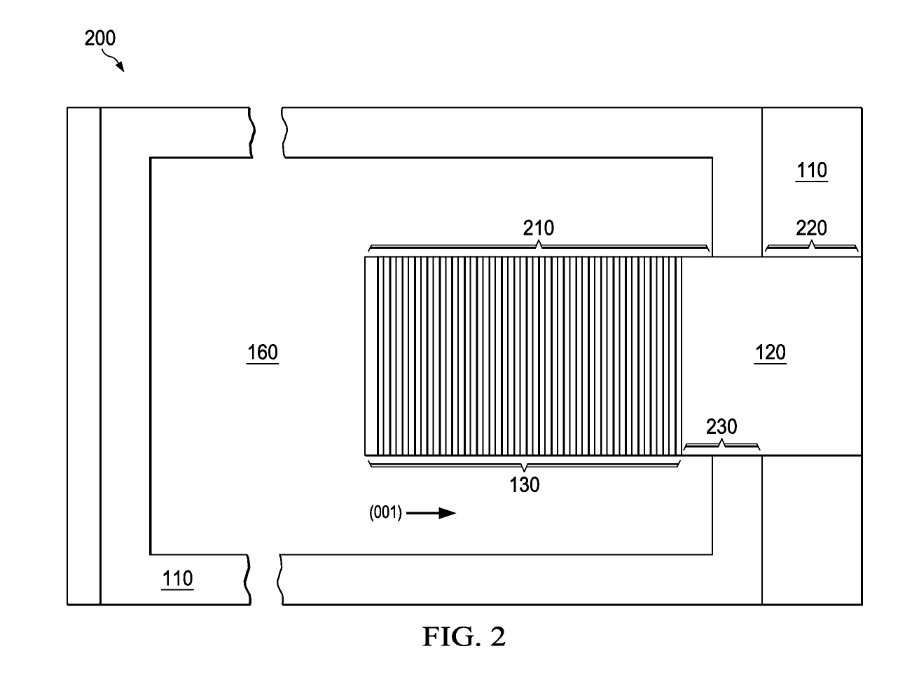

FIG. 2 illustrates an embodiment of a grating coupler that may be used, e.g. in the apparatus of FIG. 1A, including a regular array of optical scattering elements;

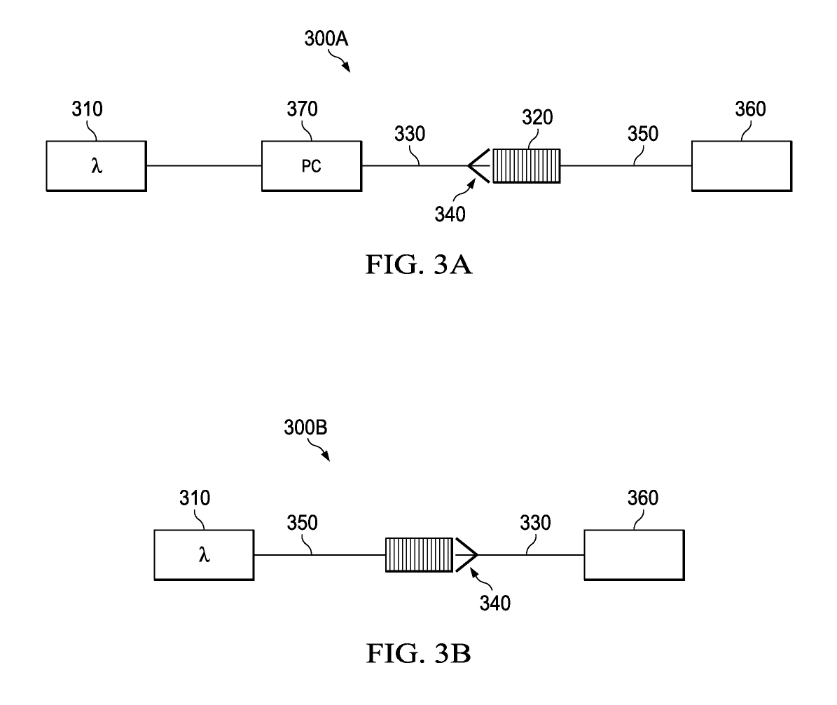

FIGS. 3A and 3B, illustrate embodiments of optical systems that include a grating coupler, such as, for example, the grating coupler of FIG. 2, configured to couple an optical signal from a fiber optical waveguide to a planar optical waveguide (FIG. 3A) or from a planar optical waveguide to a fiber optical waveguide (FIG. 3B);

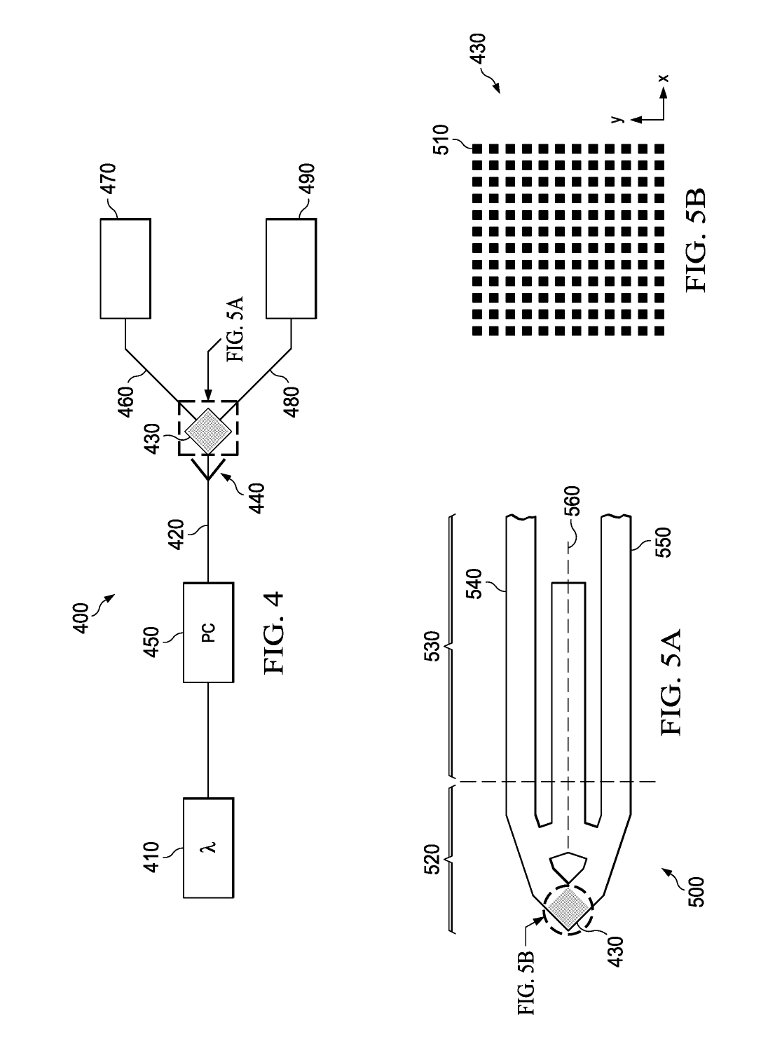

FIG. 4 illustrates an embodiment of an optical system including a grating coupler, such as, for example, the grating coupler of FIG. 5A, configured to separate polarization modes of an optical signal;

FIGS. 5A and 5B illustrate an embodiment of a grating coupler including a planar optical waveguide and a regular array of grating elements configured to separate polarization modes of an optical signal;

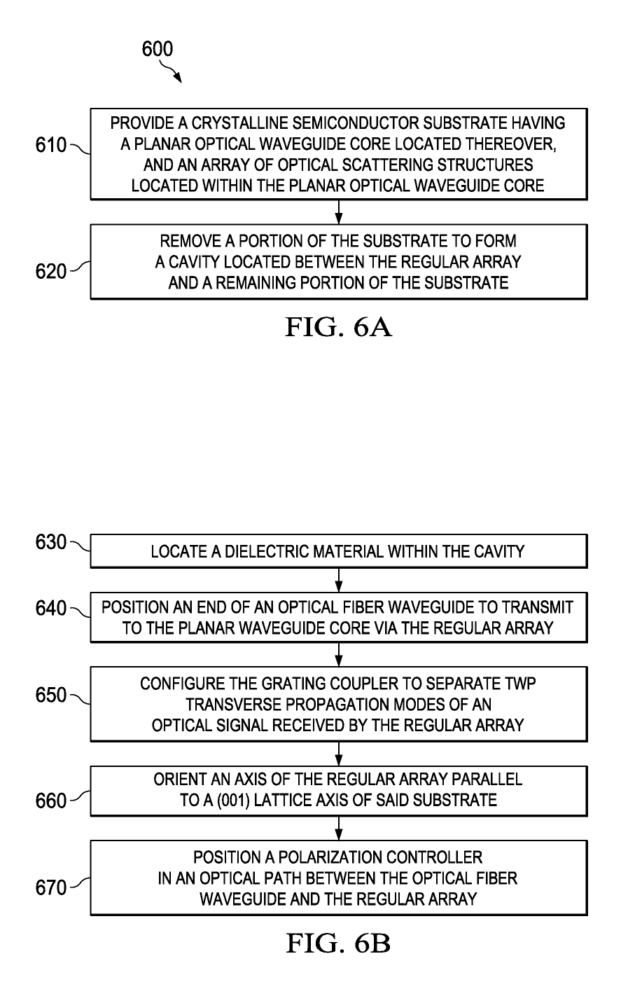

FIGS. 6A and 6B illustrate an embodiment of a method of manufacturing a grating coupler consistent with that of FIG. 2;

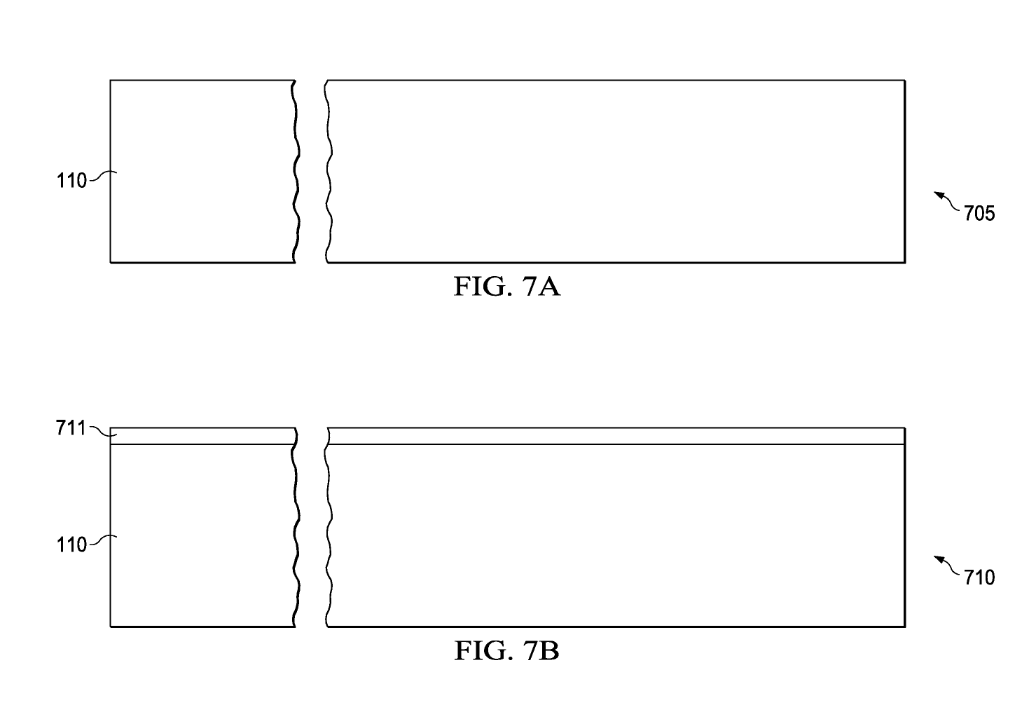

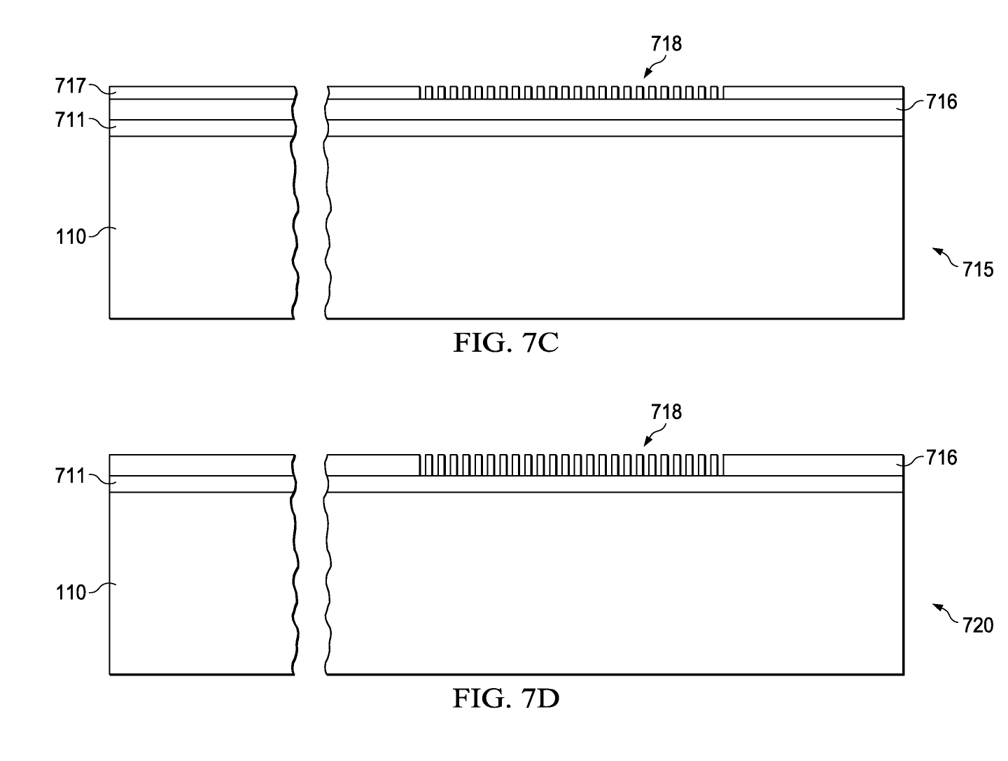

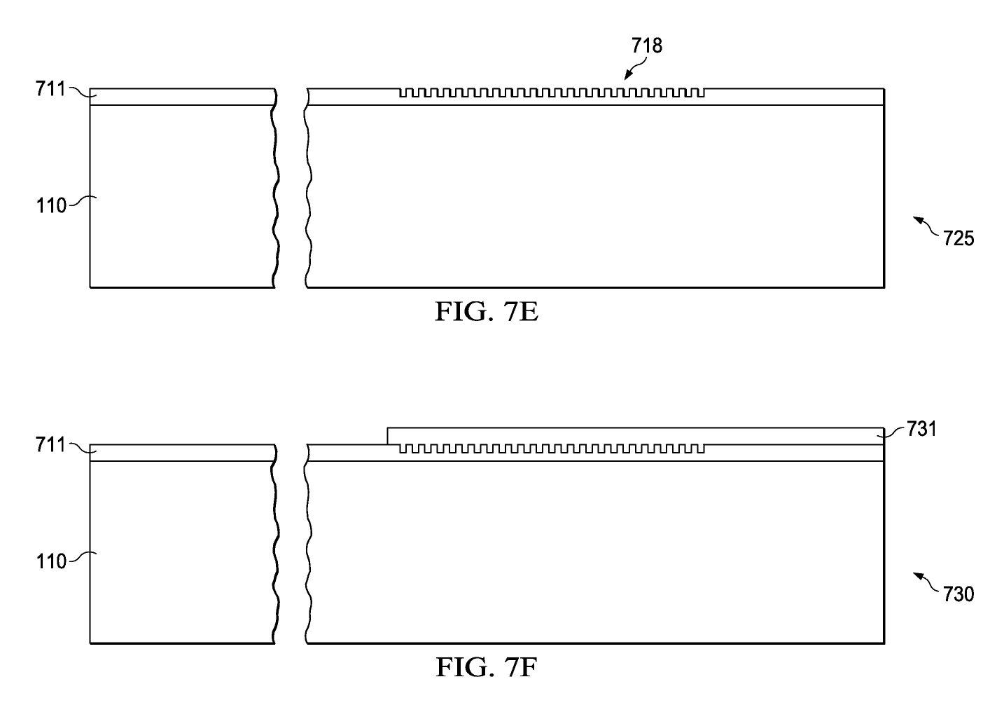

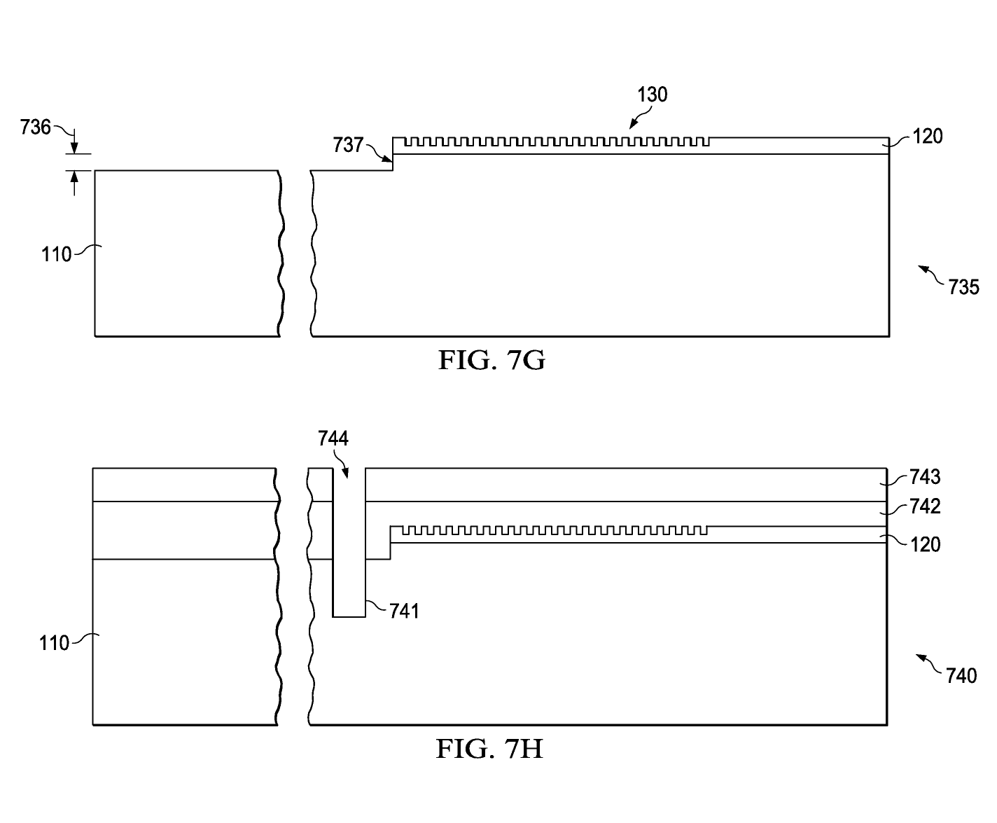

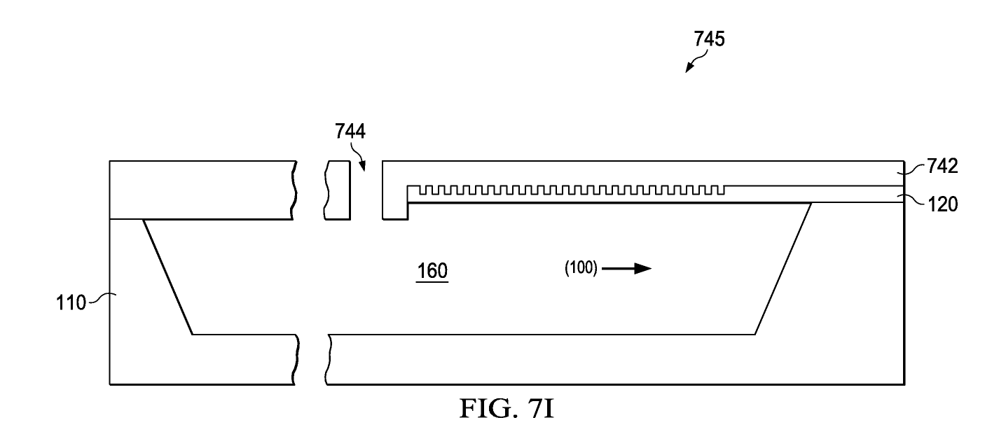

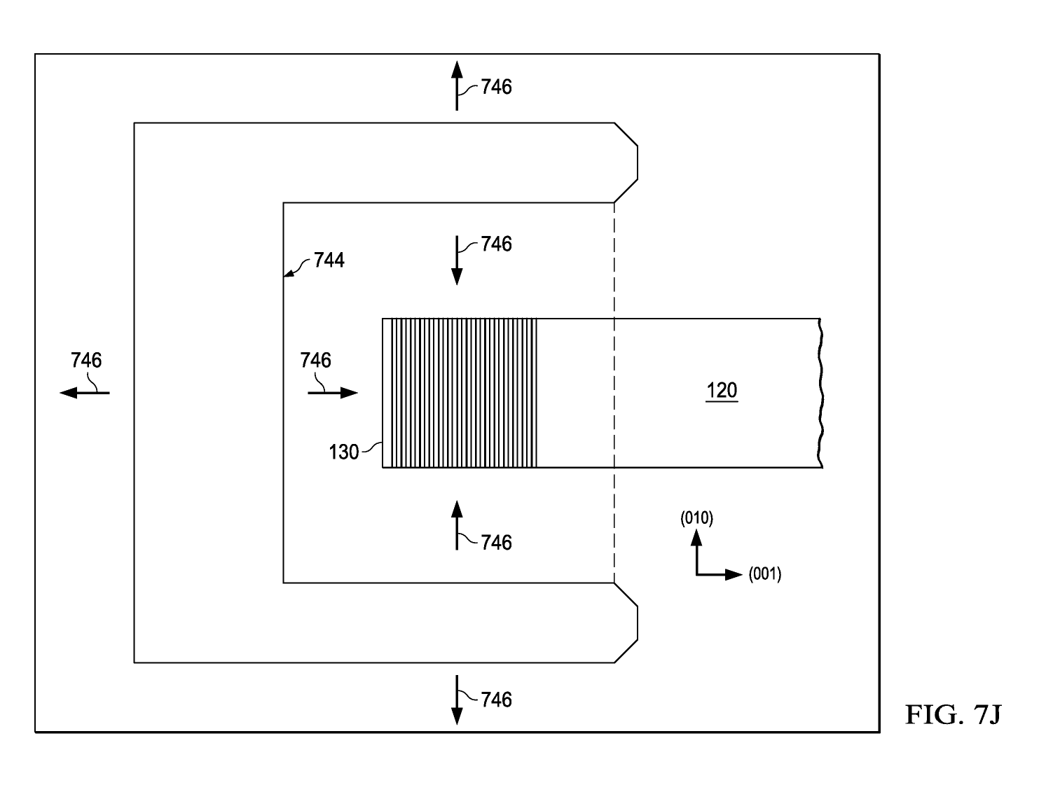

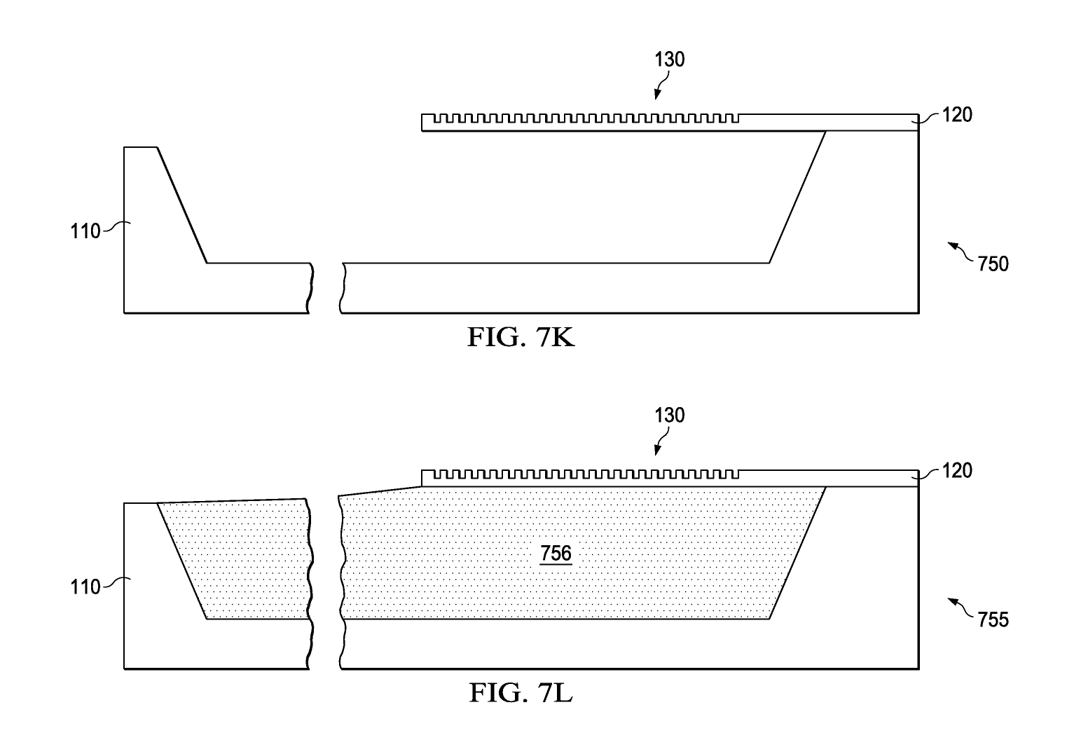

FIGS. 7A-7L illustrate an embodiment of a method of implementing the method of FIG. 6A;

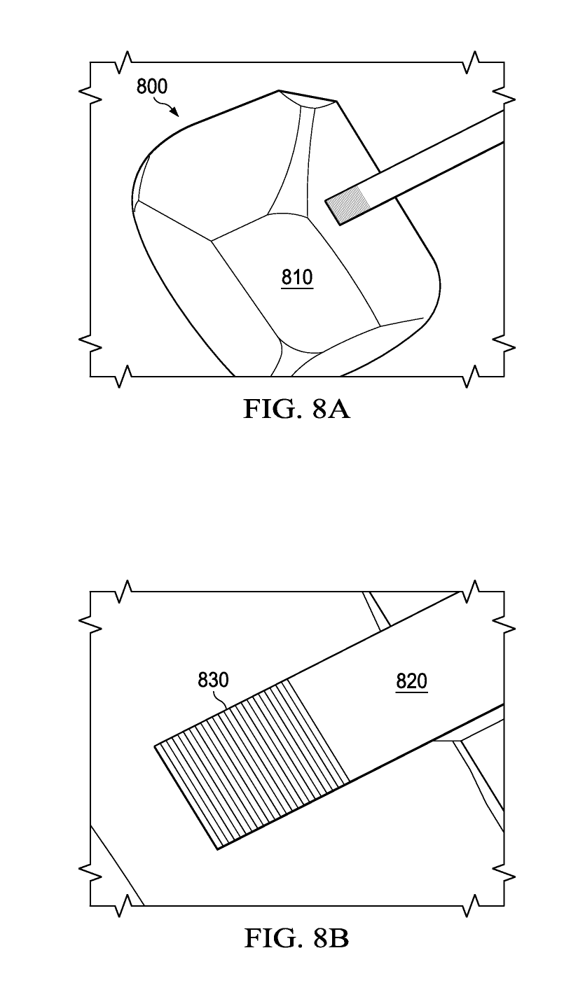

FIGS. 8A and 8B present a micrograph of an embodiment of a grating coupler consistent with that of FIG. 2 and formed by a method consistent with, e.g. the method described by FIGS. 7A-7L; and

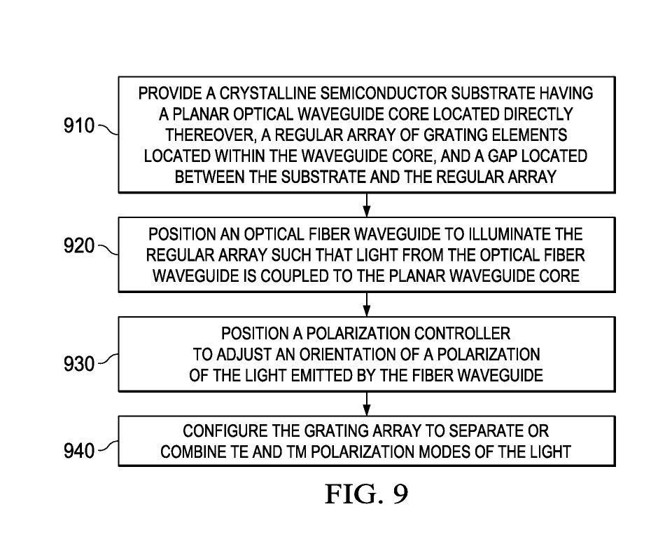

FIG. 9 illustrates an embodiment of a method of manufacturing an apparatus consistent with the apparatus of FIG. 1A.

### DETAILED DESCRIPTION

Planar optical waveguides typically have a relatively high refractive index contrast between the waveguide core and the waveguide cladding. Such waveguides may propagate a single-mode optical signal having a mode width below one micron, and thus may have a width of similar size. However, an optical fiber waveguide may propagate a single-mode optical signal having a mode width up to about ten microns, with the diameter of the fiber being of similar size. The difference in mode size results in a significant mode mismatch between the planar waveguide and the fiber waveguide. This mismatch may make difficult or impractical the coupling of the optical signal between the planar waveguide and the fiber waveguide.

Various embodiments substantially improve the optical coupling between a planar waveguide and a fiber waveguide via a regular array of grating elements in a core layer of the waveguide by forming a cavity between the regular array and an underlying substrate. The cavity increases the refractive index difference between the planar waveguide core and the planar waveguide cladding in the vicinity of the grating thereby increasing the coupling efficiency of the regular array. This increase of coupling efficiency may make practical the use of grating couplers in optical applications that would not previously have benefited from the use of such couplers.

Hereinafter, the difference of refractive index between two adjacent media is referred to as “refractive index contrast”, or simply “contrast”.

As described briefly above, in some cases a planar waveguide may have a width of a micron or less, while a fiber waveguide may have a diameter of approximately 10 μm at a wavelength of ˜1.5 μm, e.g. The difference of size in general results in a large mismatch of the propagation modes. When the mismatch is large, most of the signal may be lost to reflections and radiation between the fiber and planar waveguides.

Various approaches to mitigate the mismatch between a fiber waveguide and a planar semiconductor waveguide are possible. In one approach, a planar converter near a facet of a substrate underlying the planar waveguide is butt-coupled to the fiber. This is sometimes done with, e.g., a large-core waveguide having strong modal confinement, or a small-core waveguide having weak modal confinement. This approach can use multiple material layers to aid in size-matching the fiber mode to the planar waveguide mode, making manufacture more complex and expensive.

In another example, a grating coupler may be used to interface a fiber waveguide aligned near normal to the surface of the optical device. The grating coupler may include a periodic pattern within the planar waveguide, creating distributed scattering. With proper choice of the grating parameters, the scattering may adequately match the propagation between the fiber waveguide and the planar waveguide.

However, because the grating scatters light, a significant fraction of the energy of an optical signal may be lost at the grating. This problem is particularly acute when the refractive index of the cladding beneath the grating coupler is close to the effective refractive index of the waveguide in which the grating is formed. Such low contrast between cladding and core waveguide layers is common in planar devices based on GaAs/AlGaAs and InP/InGaAsP, but such material systems may be desirable in various planar optical waveguide applications for other reasons.

While planar grating couplers have been implemented in material systems such as silicon-on-insulator (SOI), in which the index contrast is relatively large, no implementation in known in low-contrast material systems. There seems therefore to be an unmet need in the planar optical arts to implement a grating coupler in material systems in which the index contrast is small between the waveguide core material and the substrate material.

The inventors have recognized that the limitations of above-described conventional practice of using planar grating couplers may be overcome by removing a portion of the substrate underlying the grating. In particular a pit, or cavity, is formed in the substrate under the grating, thereby reducing the refractive index of the cladding beneath the grating from the refractive index of the substrate material to the refractive index of air, e.g., about unity, or to that of a dielectric material having a low dielectric constant.

FIG. 1A illustrates a planar optical apparatus 100 that includes a grating coupler. In the apparatus 100, a semiconductor substrate 110 supports a planar waveguide core 120, having a thickness T. The planar waveguide core 120 is formed from a semiconductor layer located over the substrate 110, e.g., by conventional micro-electronics manufacturing methods, as described below. The substrate 110 adjacent to the planar waveguide core 120 may function as a waveguide cladding. The substrate 110 may be any of a variety of semiconductor materials, e.g., GaAs, or InP. A regular array of optical scattering elements forms an optical grating 130.

FIG. 1B illustrates a portion of the grating 130 in greater detail. The grating 130 is a substantially regular one-dimensional or two-dimensional array of optical scattering structures 135 located within a region of the planar waveguide core 120. The grating 130 is characterized by a grating element width W, a grating height H, and a grating pitch P, i.e., a distance between the centers of adjacent optical scattering structures 135. “Substantially regular” means that P and W are substantially constant within the grating 130, or that P and/or W varies monotonically across the grating 130, e.g., chirped.

Returning to FIG. 1A, a fiber waveguide 140 is located adjacent to the grating 130, and is configured to transmit an optical signal to, or receive an optical signal from, the planar waveguide core 120 via the grating 130. An end 145 of the fiber waveguide 140 is spaced by a gap 150, e.g., a free space gap, from the grating 130. The fiber waveguide 140 may thereby transmit an optical signal to, or receive an optical signal from, the planar waveguide core 120.

A cavity 160 in the substrate 110 is located between the grating 130 and adjacent surface of the substrate 110. Due to the cavity 160, the portion of the waveguide core 120 over the cavity is separated from the substrate 110 by a gap 165. The cavity 160 functions as a cladding for the planar waveguide core 120 in the vicinity of the grating 130. The cavity 160 has a refractive index less than that of the substrate 110. The presence of the low-index cavity 160 increases the coupling efficiency between the fiber waveguide 140 and the planar waveguide core 120 as compared to the coupling of a similar device in which the grating 130 is located directly on the substrate.

The optical signal propagating between the fiber waveguide 140 and the grating 130 may be coherent light, e.g. generated by a laser source. Such optical signals often have a Gaussian radial intensity profile and thus, are not expected to spread significantly in the free-space gap 150. Thus, the operation of the apparatus 100 is expected to be relatively insensitive to the size of the gap 150. The size of the gap 150 is not limited to any particular value. In various embodiments, the gap 150 may be about equal to or less than the diameter of the fiber waveguide 140, e.g., about 10-100 μm. Those skilled in the optical arts are capable of positioning the fiber waveguide 140 in this manner using conventional optical apparatus.

The fiber waveguide 140 may be tilted relative to a surface normal 147 of the substrate 110 by a non-zero angle α. As described further below, the coupling between the fiber waveguide 140 and the planar waveguide core 120 depends in part on the value of α. The value of α is not limited to any particular value, but is generally determined in part by the values of P, W and H (FIG. 1B). Example values for α are about 10° or less, and in some embodiments α is about 5° or less.

In cases for which the contrast between the planar waveguide core 120 and the substrate 110 is relatively small, the coupling efficiency between the fiber waveguide 140 and the planar waveguide core 120 may be reduced due to loss of optical energy to the substrate 110. In a nonlimiting example, the planar waveguide core 120 and the substrate 110 may be formed from InGaAsP and InP, respectively. InGaAsP and InP have refractive indexes at a wavelength of 1.5 μm of about 3.45 and 3.17, respectively. Thus, the contrast between an InGaAsP layer and an InP layer is about 0.28. While an optical signal is guided by the planar waveguide core 120, the contrast is small enough that a significant percentage of the energy of an optical signal being transmitted between the fiber waveguide 140 and the planar waveguide core 120 may be lost to the substrate 110, e.g. by scattering in the grating 130.

FIG. 2 illustrates a top view of one embodiment of a grating coupler 200. A first region 210 of the planar waveguide core 120 is located over the cavity 160, i.e., the cavity 160 is located between the first region 210 of the planar waveguide core 120 and the substrate 110. A second region 220 of the planar waveguide core 120 is located directly on the substrate 110. A third region 230 of the planar waveguide core 120 is located between the grating 130 and the second region 220.

In some embodiments, the cavity 160 may be filled with a dielectric material. A dielectric material within the cavity 160 may have an index of refraction below that of the substrate 110, e.g., benzocyclobutene (BCB), SiLK™, spin-on-glass, and some epoxies have refractive indexes that are lower than the indexes of typical III-V semiconductors. Such a dielectric material may physically support the first region 210 of the planar waveguide core 120 thereby providing increased mechanical strength.

The inventors believe that the process of transmitting light from the fiber waveguide 140 to the planar waveguide core 120 involves two related processes. A first process involves transmitting the light from the fiber waveguide 140 to the first region 210 of the planar waveguide core 120. A second process involves transmitting the light between the first region 210 of the planar waveguide core 120 and the second region 220 thereof. The second process has a potential for causing significant losses when there is a mismatch between propagating mode sizes in the first region 210 and the second region 220.

FIG. 3A illustrates an embodiment of a system 300A that employs a grating coupler consistent with some embodiments of the grating coupler 200 described herein. An optical source 310 is configured to output an optical signal that propagates to a grating coupler 320 via an optical path that includes a fiber waveguide 330 and a free-space path 340. A planar waveguide 350 is configured to propagate the optical signal to an optical circuit 360 that may be configured to further process the optical signal. The optical path may optionally include a polarization rotator 370 that rotates the optical signal polarization modes such that a TE or TM (transverse-magnetic) mode aligns with the grating coupler 320. Herein, a polarization mode is aligned with the grating coupler 320 when a field intensity vector, e.g., an E-field or an H-field, is about parallel to a long axis of linear grating elements, such as those of the optical grating 130, or parallel to an axis of a two-dimensional array of optical scattering structures, such as those of the optical grating 430.

The grating coupler 320 generally propagates optical energy in the aligned polarization mode, while energy that is not aligned is generally filtered out of the received optical signal.

FIG. 3B illustrates an embodiment of a system 300B, in which the optical source 310 is configured to output the optical signal to the planar waveguide 350. In this embodiment, the grating coupler is configured to couple part of the optical signal to the fiber waveguide 330 via the free-space path 340. The part of the optical signal may then propagate to the optical circuit 360 for further processing.

FIG. 4 illustrates an embodiment of a system 400 configured for polarization multiplexing of an optical signal from an optical source 410. Polarization multiplexing, e.g., simultaneous propagation of TE and TM modes, may be used to simultaneously transmit two independent data streams. A fiber waveguide 420 is configured to propagate the optical signal to an optical grating 430 via a free-space path 440. A polarization controller 450 is configurable to rotate the polarization of the optical signal in the fiber waveguide 420 such that the optical grating 430 separates the polarization modes of the optical signal. One mode, e.g., TE, may propagate via a planar waveguide 460 to an optical channel 470. Another mode, e.g., TM, may propagate via a planar waveguide 480 to an optical channel 490.

FIG. 5A illustrates an embodiment 500 of a grating coupler configured to separate the polarization modes of an optical signal. Various embodiments of the optical grating 430, illustrated in a detail view in FIG. 5B, include a square array of optical scattering structures 510. The optical scattering structures 510 are similar to the optical scattering structures 135. The optical scattering structures 510 may be, e.g., raised portions or depressions in a planar waveguide core, e.g., the waveguide core 120. The scattering structures have an associated height and width and are distributed according to a pitch. While the grating 130 has only an approximate one-dimensional periodicity, the optical grating 430 has an approximate two-dimensional periodicity. The gratings 130, 430 may however, be chirped in some embodiments, e.g., to increase their bandwidth. Analogous to the apparatus 100, the optical grating 430 is located within a region 520 that includes a planar waveguide core located over a cavity, e.g., the cavity 160. A region 530 located directly on a substrate, such as the substrate 110, includes a first polarization branch 540 and a second polarization branch 550.

The optical grating 430 has an associated x-axis and y-axis (FIG. 5B). In the illustrated embodiment, the x-axis and the y-axis may be oriented at about 45° with respect to an axis of symmetry 560, but embodiments based on other regular two-dimensional lattices may have primitive lattice vectors that are differently oriented, e.g., the primitive lattice vectors may not be relatively orthogonal. When a received optical signal is oriented such that one polarization component is parallel to the x-axis and the orthogonal polarization component is parallel to the y-axis, the polarization components of the received optical signal may be separately directed by the optical grating 430. In particular, the grating may send one polarization component into the first polarization branch 540 and send the other polarization component into the second polarization branch 550. Preferably, the optical grating 430 will substantially size-match the propagation mode of a received polarization channels to the TE propagation modes of the polarization branches 540, 550 to which the polarization channels are directed. An optional polarization controller 450 may rotate the optical signal such that the polarization modes are substantially aligned with the axes of the optical grating 430 to effect a separation of two polarization channels, e.g., aligned to within about ±10 degrees.

Turning now to FIG. 6A, an example method 600 is suitable for fabricating the apparatus 100 of FIG. 1A. The method 600 is described with references to FIGS. 7A-7J, which illustrate sectional views of the intermediate structures for the apparatus 100 during fabrication.

The method 600 begins with a step 610 in which the crystalline semiconductor substrate 110 is provided. The substrate 110 has a planar optical waveguide core located thereover, and a regular array of optical scattering structures located within the planar optical waveguide core.

FIGS. 11A-11G illustrate one embodiment of a method of fabricating the planar waveguide core 120 and the associated grating 130. In FIG. 7A, the substrate 110 is provided in a step 705. In one embodiment, the substrate 110 is a (100) InP wafer. In some cases it may be advantageous to have a flat of the wafer oriented along the [011] direction of the wafer.

FIG. 7B illustrates a step 710, in which a waveguide core layer 711 is formed on the substrate 110. The waveguide core layer 711 may be epitaxially grown on the substrate 110 using a metal-organic chemical vapor deposition process, or may be transferred from another substrate via a wafer bonding process, e.g. Both of these techniques are known to those skilled in the pertinent art. In various embodiments the thickness of the waveguide core layer 711 is chosen for a desired wavelength of operation, e.g., wavelengths in the telecommunications C and/or F bands. In an embodiment, the waveguide core layer 711 has a thickness of about 380 nm for operating wavelengths in the telecommunications C-band. The composition of the core layer 711 may be characterized by a photoluminescence peak wavelength. In various embodiments the core layer 711 is an InGaAsP layer with a photoluminescence peak wavelength of about 1.37 μm.

In FIG. 7C, illustrating a step 715, a hardmask 716, that may be a CVD silicon oxide layer, is formed over the waveguide core layer 711. Those skilled in the pertinent art understand that the thickness of the hardmask 716 may be chosen as appropriate for a particular manufacturing tool set and later etch process. In one embodiment, the hardmask 716 is about 60 nm thick. A photoresist layer 717 is formed on the hardmask 716 and patterned with a grating pattern 718 by a patterning process that may include conventional electron-beam or submicron optical lithography. The thickness of the photoresist layer 717 may be, e.g., about 200 nm.

In FIG. 7D, illustrating a step 720, the grating pattern 718 has been conventionally transferred to the hardmask 711 to form the grating 130. A conventional plasma etch process, e.g., reactive-ion etch, may be used to effect the transfer. Any portions of the photoresist layer 717 that remain after the etch process may be removed by, e.g., a plasma etch and/or a solvent clean.

FIG. 7E illustrates a step 725, in which the pattern 718 is transferred to the waveguide core layer 711 to form the grating 130. The transfer process may be a conventional plasma etch process, e.g., reactive-ion etch. The target depth D of the grating 130 (FIG. 1B) is selected based on the intended wavelength of the operation of the apparatus 100. In a nonlimiting embodiment, D is about 200 nm for an operating wavelength of 1.5 μm. Those skilled in the pertinent art will appreciate that D will vary somewhat over the grating 130 due to variations in the etch process.

FIGS. 11F and 11G illustrate formation of the planar waveguide core 120. In a step 730 (FIG. 7F), a patterned hardmask layer 731 is formed over the waveguide core layer 711. The patterned hardmask layer 731 may be formed conventionally from a continuous CVD silicon oxide layer (not shown). Similarly to steps 715-725, the continuous oxide layer may be patterned via a photoresist layer (not shown) and a conventional plasma etch, e.g., RIE, to form the patterned hardmask layer 731 with the appropriate pattern for the planar waveguide core 120. In a step 735 (FIG. 7G), a conventional etch process transfers the pattern defined by the hardmask layer 731 to the layer 711 to define the planar waveguide core 120. In the illustrated embodiment, a portion 736 of the substrate 110 is also removed by the etch process. This removal has the effect of forming a ridge 737 under the planar waveguide core 120. Such a ridge reduces the coupling of an optical signal traversing the planar waveguide core 120 to the substrate 110. In some embodiments the etch process removes about 1.5 μm of the substrate 110, but embodiments of the disclosure are not limited to any particular amount of removal.

Returning to FIG. 6A, in a step 620, a portion of the substrate 110 is removed to form the cavity 160 located between the regular array and a remaining portion of the substrate 110.

FIGS. 11H-J illustrate one example embodiment of formation of the cavity 160. In a step 740, a trench 741 is formed in the substrate 110. In the illustrated embodiment, a CVD silicon oxide layer 742 has been conventionally formed over the substrate 110, and a photoresist layer 743 has been formed thereover. An opening 744 has been formed in the photoresist layer 743 and transferred to the oxide layer 742 and the substrate 110 via a conventional etch process, e.g. a plasma etch, thereby forming the trench 741. The trench 741 may be etched to a depth of, e.g., about 7 μm into the substrate 110. The photoresist layer 743 may be removed after forming the trench 741.

In a step 745 (FIG. 71), the cavity 160 is formed by, e.g., a wet etch process. As will appreciated by those skilled in the pertinent art, the specifics of wet etching a semiconductor substrate will depend on, e.g., the crystal plane presented at the surface of the substrate 110 and the orientation of the cavity 160 with respect to the substrate 110 lattice. Using InP as a non-limiting example for the substrate, exposed surfaces of the substrate 110 may be etched using a room temperature mixture of hydrochloric acid and phosphoric acid with a ratio of, e.g., about 3 parts hydrochloric acid to 1 part phosphoric acid for about 3.5 min. Other substrate 110 materials will in general be etched by other conventionally known wet etchants and/or other ratios of the etchants used. Other enchants and materials may require different etch times.

Those skilled in the pertinent art will also appreciate that the etch rate of an exposed surface of the substrate 110 may be highly dependent on the orientation of the substrate 110 lattice with respect to the exposed surface. Thus, for example, a (111) surface may etch considerably slower than a (100) surface. The differential etch rate typically results in faceting of the cavity 160.

In various embodiments, the expected different etch rates of the various crystal planes of the substrate 110 is considered in placing the planar waveguide core 120 and the grating 130. For example, in some embodiments a long axis of the planar waveguide core 120 is oriented parallel the (001) axis of the substrate 110 lattice. The (001) axis generally has a greater etch rate than, e.g., the (111) direction. In this way, the etch will undercut the planar waveguide core 120, desirably exposing the underside of the planar waveguide core 120 (e.g., the side of the planar waveguide core 120 formerly in contact with the substrate 110).

FIG. 7J illustrates a top view of an embodiment of the opening 744. In some embodiments, such as the illustrated embodiment, the opening 744 is formed in manner that takes into account the differential etch rates of the exposed crystal faces of the substrate 110 to produce a desired profile of the cavity 160. In the illustrated example, the opening 744 forms a “C” around the grating 130. The substrate 110 is removed more rapidly in (001) lattice directions 746, resulting in a profile of the cavity 160 similar to that illustrated in FIG. 71. In contrast, in the hypothetical case of a simple opening, e.g., a square, in the oxide layer 742, the trench 741 would be expected to form a cavity with walls defined by (111) planes of the substrate 110 lattice. Such a cavity would be expected to etch slowly and have a pyramidal profile that is considered generally undesirable. In spite of these drawbacks, such a cavity is within the scope of the embodiments described herein.

FIG. 7K illustrates the apparatus 100 after removal of the oxide layer 742. The removal may be conventionally performed by, e.g., a wet etch selective to the substrate 110, for example HF. The grating 130 may be integrated with the fiber waveguide 140 as previously described to form the apparatus 100.

FIG. 6B presents various steps that may optionally be performed with the method 600. Though presented in the illustrated order, these steps may be performed, if at all, in different orders.

In an optional step 630 a dielectric material is located within the cavity 160. FIG. 7L illustrates an embodiment in which the cavity 160 is filled with a dielectric material 756. As described previously, various spin-on dielectric materials used in integrated circuit processing may be used, such as, e.g., BCB, SiLK™, spin-on-glass, or epoxy. However, other conventional spin-on dielectric material may be used in other embodiments. The dielectric material 756 may be applied by spin casting a solution of the dielectric material 756. Optionally, the excess spin-on dielectric material may be removed from the surface of the substrate 110 with plasma etch-back, as in the illustrated embodiment.

With continued reference to FIG. 6B, in an optional step 640 an optical fiber waveguide such as the fiber waveguide 140 is positioned such that an end thereof may transmit to the planar optical waveguide core 120 via the grating 130. This step is illustrated, e.g., by the systems 300A, 300B of FIGS. 3A and 3B.

In an optional step 650, the grating is constructed to be able to separate two transverse polarization components of an optical signal received by the grating. This step is illustrated, e.g., by the system 400 of FIG. 4.

In an optional step 660, an axis of the regular array is arranged parallel to a (001) lattice axis of the substrate. This step is illustrated, e.g., by the arrangement of the optical scattering structures 135 parallel to the (010) axis in FIG. 7J.

In an optional step 670, a polarization controller is positioned in an optical path between the optical fiber waveguide and the regular array. This step is illustrated, e.g., by the system 300A of FIG. 3A.

Turning now to FIGS. 8A and 8B, illustrated are a lower magnification (FIG. 8A) and a higher magnification (FIG. 8B) view of a fabricated grating coupler 800. FIG. 8A illustrates various features previously described, such as a cavity 810, and a planar waveguide 720 overhanging the cavity 720. FIG. 8B illustrates the planar waveguide 820 in greater detail, including an optical grating 830.

Coupling between the fiber waveguide 140 and the planar waveguide core 120 was simulated numerically for a grating coupler represented by the grating coupler 800. The simulation was performed for a thickness T of 380 nm for the planar waveguide core 120, a grating pitch P of 580 nm and a grating height H of 200 nm. An optical signal was modeled without limitation as a TE-polarized Gaussian beam. The direction of the optical signal was tilted 5° with respect to the surface normal of the planar waveguide 120. The estimated energy coupling efficiency was determined to be about 45%.

Simulation of a similar grating coupler lacking a cavity between the planar waveguide core and the substrate resulted in an energy coupling efficiency of less than about 10%. Thus, embodiments described herein may result in energy coupling efficiency at least a factor of four greater than a similar grating coupler lacking a cavity. It is expected that the coupling efficiency may be improved by optimization of device geometry, e.g.

Turning now to FIG. 9, a method 900 is illustrated. The method 900 may be employed, e.g., in configuring an optical system using a grating coupler having the features described herein.

In a step 910, a crystalline semiconductor substrate is provided that has a planar waveguide core located directly thereover. A regular array of optical scattering structures is located within the waveguide core, and a gap such as the gap 165 (FIG. 1A) is located between the substrate and the regular array. Such a substrate is described, e.g., by the embodiment illustrated in FIG. 7K.

In a step 920, an optical fiber waveguide is configured to illuminate the regular array of optical scattering structures.

In an optional step 930, a polarization controller is constructed to control an orientation of a polarization mode of the light emitted by the fiber waveguide. Such a configuration is illustrated, e.g., by the system 400 of FIG. 4.

In an optional step 940, the grating coupler is configured to separate or combine two transverse polarization components, e.g., TE and TM, of the light transmitted between the fiber waveguide 140 and the grating 130. Such a configuration is illustrated, e.g., by the embodiment 500 of FIG. 5A.

Those skilled in the art to which this application relates will appreciate that other and further additions, deletions, substitutions and modifications may be made to the described embodiments.

What is claimed is:

1. An apparatus, comprising:
a crystalline inorganic semiconductor substrate;
a planar optical waveguide core located over said substrate such that a first length of said planar optical waveguide core is directly on said substrate;
a regular array of optical scattering structures located within a second length of said planar optical waveguide core; and
a cavity located in said substrate between said regular array and said substrate.

2. The apparatus of claim 1, wherein said substrate and said planar optical waveguide core comprise In and P.

3. The apparatus of claim 1, wherein said regular array is configured to couple an optical signal between said planar optical waveguide core and an optical fiber waveguide.

4. The apparatus of claim 3, wherein an energy coupling efficiency between said planar optical waveguide core and said optical fiber waveguide is at least 40%.

5. The apparatus of claim 3, further comprising an optical polarization controller configured to adjust an orientation of a polarization of light transmitted from said optical fiber to said regular array.

6. The apparatus of claim 1, wherein said regular array comprises a two-dimensional regular array constructed to direct first and second relatively orthogonal polarization components in different directions.

7. The apparatus of claim 1, wherein said regular array of scattering structures is located along a plane perpendicular to a (001) lattice direction of said substrate.

8. The apparatus of claim 1, further comprising a dielectric material located within said cavity.

9. The apparatus of claim 1, wherein said regular array is chirped.

10. A method, comprising:
providing a crystalline semiconductor substrate having a planar optical waveguide core located directly thereover and a regular array of optical scattering structures located within said planar optical waveguide core; and
removing a portion of said substrate to form a cavity located between said regular array and a remaining portion of said substrate.

11. The method of claim 10, wherein said substrate and said planar optical waveguide core comprise In and P.

12. The method of claim 10, further comprising locating a dielectric material within said cavity.

13. The method of claim 10, further comprising positioning an end of an optical fiber waveguide to transmit to said planar optical waveguide core via said regular array.

14. The method of claim 13, further comprising positioning a polarization controller in an optical path between said optical fiber waveguide and said regular array.

15. The method of claim 10, wherein said regular array is chirped.

16. A method, comprising:
providing a crystalline semiconductor substrate having a planar optical waveguide core located directly thereover, a regular array of optical scattering structures located within said planar optical waveguide core, and a gap located between said substrate and said regular array; and
positioning an optical fiber waveguide to illuminate said regular array such that light from said optical fiber waveguide is coupled to said planar waveguide core.

17. The method of claim 16, wherein said regular array is configured to couple said light from said fiber waveguide to said planar optical waveguide core with an energy coupling efficiency of at least about 40%.

18. The method of claim 16, wherein said semiconductor substrate comprises InP and said planar waveguide comprises InGaAsP.

19. The method of claim 16, further comprising positioning a polarization controller to adjust an orientation of a polarization of said light emitted by the fiber waveguide.

20. The method of claim 16, further comprising configuring said regular array to differently direct two polarization components of said light received from said fiber waveguide.
